(19) United States
(12) Patent Application Publication
(10) Pub. No.: US 2026/0026015 A1
(43) Pub. Date: Jan. 22, 2026

(54) SEMICONDUCTOR DEVICES

(71) Applicant: Samsung Electronics Co., Ltd., Suwon-si (KR)

(72) Inventors: Taejin PARK, Suwon-si (KR); Cheonbae KIM, Suwon-si (KR); Sungsoo YIM, Suwon-si (KR)

(21) Appl. No.: 19/234,466

(22) Filed: Jun. 11, 2025

(30) Foreign Application Priority Data
Jul. 22, 2024 (KR) 10-2024-0096071

(51) Int. Cl. H10B 80/00; H01L 23/00; H01L 25/00; H01L 25/065; H01L 25/18; H10B 12/00

(52) U.S. Cl. CPC H10B 80/00; H01L 24/05; H01L 24/08; H01L 24/80; H01L 25/0657; H01L 25/18; H01L 25/50; H10B 12/315; H01L 2224/05147; H01L 2224/05187; H01L 2224/08145; H01L 2224/80895; H01L 2224/80896; H01L 2924/0509; H01L 2924/1431; H01L 2924/1436

(57) ABSTRACT

A semiconductor device may include a transistor on a substrate, a first wiring structure on the transistor, a first bonding pad structure on the first wiring structure, a second wiring structure on the first wiring structure and at least partially overlapping the first bonding pad structure in a horizontal direction, a second bonding pad structure on and spaced apart from the second wiring structure and overlapping the first bonding pad structure in the horizontal direction, a bit line structure on the first and second bonding pad structures, a gate structure on the bit line structure, a channel adjacent to the gate structure and in contact with the bit line structure, and a capacitor on the channel.

### CROSS-REFERENCE TO RELATED APPLICATION

This application claims priority under 35 U.S.C. § 119 to Korean Patent Application No. 10-2024-0096071 filed on Jul. 22, 2024 in the Korean Intellectual Property Office, the disclosure of which is hereby incorporated by reference in its entirety.

### BACKGROUND

The present inventive concept relates generally to a semiconductor device and, more particularly, to a semiconductor device having an increased degree of freedom with respect to a wiring layout of the device.

In a method of manufacturing a semiconductor device, a substrate on which periphery circuit pattern is formed and a substrate on which memory cells are formed may be bonded to each other by a hybrid copper bonding (HCB) process through a bonding layer and a bonding pad. A plurality of bonding pads may be spaced apart from each other in a horizontal direction, and may be electrically connected to wirings disposed over the bonding pads to transfer electrical signals to the wirings. Thus, a layout of the wirings is limited by a layout of the bonding pads.

### SUMMARY

Example embodiments provide a semiconductor device having improved characteristics.

According to example embodiments, there is a provided a semiconductor device. A semiconductor device may include a transistor on a substrate, a first wiring structure on the transistor, a first bonding pad structure on the first wiring structure, a second wiring structure on the first wiring structure and at least partially overlapping the first bonding pad structure in a horizontal direction parallel to an upper surface of the substrate, a second bonding pad structure on and spaced apart from the second wiring structure and overlapping the first bonding pad structure in the horizontal direction, a bit line structure on the first and second bonding pad structures, a gate structure on the bit line structure, a channel adjacent to the gate structure and being in contact with the bit line structure, and a capacitor on the channel.

According to example embodiments, there is a provided a semiconductor device. A semiconductor device may include a transistor on a substrate, a first wiring structure on the transistor, a first bonding pad on the first wiring structure, a second wiring structure on the first wiring structure and partially overlapping the first bonding pad in a horizontal direction parallel to an upper surface of the substrate, a second bonding pad in contact with an upper surface of the first bonding pad, a third bonding pad in contact with an upper surface of the second wiring structure, being spaced apart from the second bonding pad and overlapping the second bonding pad in the horizontal direction, a third wiring structure on the second and third bonding pads, a fourth wiring structure between the third bonding pad and the third wiring structure and being spaced apart from the third bonding pad, a bit line structure on the third wiring structure, a gate structure on the bit line structure, a channel adjacent to the gate structure and being in contact with the bit line structure, and a capacitor on the channel.

According to example embodiments, there is a provided a semiconductor device. A semiconductor device may include a transistor on a substrate, a first wiring structure on the transistor, a first bonding pad on the first wiring structure, a second wiring structure on the first wiring structure and at least partially overlapping the first bonding pad in a horizontal direction parallel to an upper surface of the substrate, a second bonding pad on and spaced apart from the second wiring structure and overlapping the first bonding pad in the horizontal direction, a third bonding pad in contact with an upper surface of the first bonding pad, a third wiring structure on the second and third bonding pads, a fourth wiring structure between the second bonding pad and the third wiring structure and being in contact with the third bonding pad, a bit line structure on the third wiring structure, a gate structure on the bit line structure, a channel adjacent to the gate structure and being in contact with the bit line structure, and a capacitor on the channel.

In the semiconductor device in accordance with example embodiments, a portion of the wiring structure may be disposed in spaces over and/or under the bonding pads for bonding upper and lower structures, respectively, so that a degree of freedom of a layout of the wiring structure may be increased, and that an integration degree of the semiconductor device including the wiring structure may be increased.

### BRIEF DESCRIPTION OF THE DRAWINGS

The above and other aspects, features, and advantages of the present disclosure will be more clearly understood from the following detailed description, taken in conjunction with the accompanying drawings, wherein like reference numerals (when used) indicate corresponding elements throughout the several views, and in which:

FIG. 1 is a schematic cross-sectional view illustrating a semiconductor device in accordance with example embodiments;

FIGS. 2 to 18 are schematic cross-sectional views and schematic plan views illustrating intermediate processes in a method of manufacturing a semiconductor device in accordance with example embodiments;

FIGS. 19 and 20 are schematic cross-sectional views illustrating semiconductor devices in accordance with example embodiments;

FIG. 21 is a schematic cross-sectional view illustrating a semiconductor device in accordance with example embodiments;

FIGS. 22 and 23 are schematic cross-sectional views illustrating intermediate processes in a method of manufacturing a semiconductor device in accordance with example embodiments.

FIG. 24 is a schematic cross-sectional view illustrating a semiconductor device in accordance with example embodiments; and

FIG. 25 is a schematic cross-sectional view illustrating a method of manufacturing a semiconductor device in accordance with example embodiments.

### DETAILED DESCRIPTION

The above and other aspects and features of a semiconductor device and a method of manufacturing the same in accordance with example embodiments will become readily understood from the detailed descriptions that follow, with reference to the accompanying drawings. It will be understood that, although ordinal terms such as “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process and are not necessarily intended to convey any particular order, unless the context suggests otherwise. Thus, a first material, layer (film), region, electrode, pad, pattern, structure and process discussed below could be termed a second or third material, layer (film), region, electrode, pad, pattern, structure and process without departing from the teachings of inventive concepts.

Hereinafter, in the specification (and not necessarily in the claims), two directions that are substantially perpendicular to each other among horizontal directions, which are substantially parallel to an upper surface of each of first, second and third substrates, may be referred to as first and second directions D1 and D2, respectively, and a vertical direction substantially perpendicular to the upper surface of each of the first to third substrates may be referred to as a third direction D3. In example embodiments, the first and second directions D1 and D2 may be orthogonal to each other. Each of the first to third directions D1, D2 and D3 may include not only a direction shown in the drawings but also a direction that is opposite thereto.

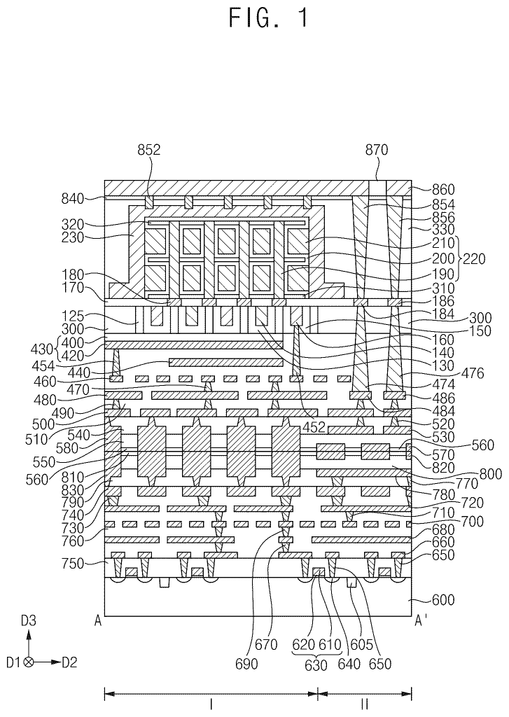

FIG. 1 is a schematic cross-sectional view illustrating a semiconductor device in accordance with example embodiments.

Referring to FIG. 1, the semiconductor device may include a periphery circuit pattern on a third substrate 600 including first and second regions I and II, and memory cells on the periphery circuit pattern, and thus the semiconductor device may have a cell over periphery (COP) structure.

However, the inventive concept is not limited thereto, and for example, the semiconductor device may have a periphery over cell (POC) structure.

The semiconductor device may include a transistor, a bit line structure 430, first and second gate structures, a channel 125, a capacitor 220, a plate electrode 230, first to third conductive pads 180, 184 and 186, a bonding layer structure, first and second bonding pad structures, and a wiring structure. The wiring structure may include, e.g., wirings, vias, and contact plugs.

The semiconductor device may further include first to eleventh insulating interlayers 750, 760, 790, 800, 300, 170, 330, 510, 540, 550 and 870.

The second region II of the third substrate 600 may surround the first region I, or may be disposed at a side or both sides in the horizontal direction, however, the inventive concept is not limited thereto. The term “surround” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. The third substrate 600 may include a semiconductor material, e.g., silicon, germanium, silicon-germanium, etc.

An isolation pattern 605 may be disposed on the third substrate 600. The isolation pattern 605 may include an oxide, e.g., silicon oxide.

The transistor may include, e.g., a third gate structure 630 on the third substrate 600 and impurity regions 640 at upper portions of the third substrate 600 adjacent to the third gate structure 630. The transistor may be a portion of the periphery circuit pattern, and a plurality of transistors may be spaced apart from each other in the horizontal direction (e.g., direction D2).

The third gate structure 630 may include a third gate insulating pattern 620 and a third gate electrode 610 stacked in the third direction D3. The third gate electrode 610 may include a conductive material, e.g., a metal, a metal nitride, a metal silicide, doped polysilicon, etc., and the third gate insulating pattern 620 may include an oxide, e.g., silicon oxide.

The first insulating interlayer 750 may be disposed on the third substrate 600, and may cover the transistor. The term “cover” (or “covering,” or like terms), as may be used herein, is intended to broadly refer to an element, structure or layer that is on or over another element, structure or layer, either directly or with one or more other intervening elements, structures or layers therebetween. A first contact plug 650 may extend through the first insulating interlayer 750, and may contact an upper surface of the impurity region 640. The term “contact” (or “contacting,” or like terms, such as “connect” or “connecting”), as may be used herein, is intended to refer to a physical and/or electrical connection between two or more elements, and may include other intervening elements. As used herein, the term “and/or” includes any and all combinations of one or more of the associated listed items.

First to fifth wirings 660, 680, 700, 720 and 740, and first to fourth vias 670, 690, 710 and 730 may be disposed on the first insulating interlayer 750 and the first contact plug 650. The second insulating interlayer 760 may be disposed on the first insulating interlayer 750, and may cover the first to fifth wirings 660, 680, 700, 720 and 740, and the first to fourth vias 670, 690, 710 and 730. The first via 670 may be disposed between the first and second wirings 660 and 680, the second via 690 may be disposed between the second and third wirings 680 and 700, the third via 710 may be disposed between the third and fourth wirings 700 and 720, and the fourth via 730 may be disposed between the fourth and fifth wirings 720 and 740.

The third and fourth insulating interlayers 790 and 800, and a first bonding layer 810 may be sequentially stacked in the third direction D3 on the second insulating interlayer 760 and the fifth wiring 740.

In example embodiments, a fifth via 770 and a sixth wiring 780 may be disposed on the second region II of the third substrate 600. The fifth via 770 may contact an upper surface of the fifth wiring 740, and the sixth wiring 780 may contact an upper surface of the fifth via 770.

A first bonding pad 820 may extend through the first bonding layer 810 and an upper portion of the fourth insulating interlayer 800 on the second region II of the third substrate 600, and may have a first thickness in the third direction D3. A plurality of first bonding pads 820 may be spaced apart from each other in the horizontal direction on the second region II of the third substrate 600.

In example embodiments, the first bonding pad 820 may not contact the sixth wiring 780, and thus not be electrically connected to the sixth wiring 780.

A second bonding pad 830 may extend through the first bonding layer 810, the fourth insulating interlayer 800 and the third insulating interlayer 790, and may contact an upper surface of the fifth wiring 740. Thus, the second bonding pad 830 may be electrically connected to the fifth wiring 740.

The second bonding pad 830 may have a second thickness in the third direction D3 greater than the first thickness. In example embodiments, the second bonding pad 830 may include a lower portion, and an upper portion, which may be stacked on the lower portion and have a thickness greater than that of the lower portion. The thickness in the third direction D3 of the upper portion of the second bonding pad 830 may be greater than the first thickness.

In example embodiments, a plurality of second bonding pads 830 may be spaced apart from each other in the horizontal direction on the first region I of the third substrate 600.

In an example embodiment, widths in the horizontal direction of the first and second bonding pads 820 and 830 may be the same as each other, however, the inventive concept is not limited thereto. In an example embodiment, a distance between the second bonding pads 830 on the first region I of the third substrate 600 may be the same as a distance between the first bonding pads 820 on the second region II of the third substrate 600, however, the inventive concept is not limited thereto.

A second bonding layer 560 and the tenth and ninth insulating interlayers 550 and 540 may be sequentially stacked in the third direction D3 on the first bonding layer 810 and the first and second bonding pads 820 and 830.

In example embodiments, a seventh via 520 and a thirteenth wiring 530 may be disposed on the second region II of the third substrate 600. The seventh via 520 may contact an upper surface of a twelfth wiring 500.

A third bonding pad 570 may extend through the second bonding layer 560 and a lower portion of the tenth insulating interlayer 550 on the second region II of the third substrate 600, and may have a third thickness in the third direction D3. A plurality of third bonding pads 570 may be spaced apart from each other in the horizontal direction on the second region II of the third substrate 600.

In example embodiments, the third bonding pad 570 may not contact the thirteenth wiring 530, and thus may not be electrically connected to the thirteenth wiring 530.

A fourth bonding pad 580 may extend through the second bonding layer 560, the tenth insulating interlayer 550 and the ninth insulating interlayer 540, and may contact a lower surface of the twelfth wiring 500. Thus, the fourth bonding pad 580 may be electrically connected to the twelfth wiring 500.

The fourth bonding pad 580 may have a fourth thickness greater than the third thickness in the third direction D3. In example embodiments, the fourth bonding pad 580 may include a lower portion, and an upper portion, which may be stacked on the lower portion and have a thickness greater than that of the lower portion. The thickness in the third direction D3 of the lower portion of the fourth bonding pad 580 may be greater than the third thickness.

In example embodiments, a plurality of fourth bonding pads 580 may be spaced apart from each other in the horizontal direction on the first region I of the third substrate 600.

In an example embodiment, widths in the horizontal direction of the third and fourth bonding pads 570 and 580 may be the same as each other, however, the inventive concept is not limited thereto. In an example embodiment, a distance between the fourth bonding pads 580 on the first region I of the third substrate 600 may be the same as a distance between the third bonding pads 570 on the second region II of the third substrate 600, however, the inventive concept is not limited thereto.

In example embodiments, the first and second bonding layers 810 and 560 may be bonded to each other on the first and second regions I and II of the third substrate 600 to form a bonding layer structure. The first and third bonding pads 820 and 570 may be bonded to each other on the second region II of the third substrate 600 to form a first bonding pad structure. The second and fourth bonding pads 830 and 580 may be bonded to each other on the first region I of the third substrate 600 to form a second bonding pad structure.

In example embodiments, the first bonding pad structure may have a pillar shape with a constant width in horizontal direction, and the second bonding pad structure may include a middle portion with a first width in the horizontal direction, and lower and upper portions with a second width in the horizontal direction smaller than the first width in the horizontal direction.

In example embodiments, widths in the horizontal direction of the first and third bonding pads 820 and 570 may be the same as each other, sidewalls of the first and third bonding pads 820 and 570 may be aligned with each other in the third direction D3, and widths in the horizontal direction of the second and fourth bonding pads 830 and 580 may be the same as each other, and sidewalls of the second and fourth bonding pads 830 and 580 may be aligned with each other in the third direction D3, however, the inventive concept is not limited thereto.

In example embodiments, the first bonding pad structure on the second region II of the third substrate 600 may not contact or be electrically connected to a portion of the wiring structure, while the second bonding pad structure on the first region I of the third substrate 600 may contact or be electrically connected to a portion of the wiring structure.

In example embodiments, the fifth via 770 and the sixth wiring 780 may be disposed on the second region II of the third substrate 600, and at least partially overlap the first bonding pad structure in the third direction D3. The fifth via 770 and the sixth wiring 780 may be disposed at the same level as a portion of the second bonding pad 830 on the first region I of the third substrate 600, and at least partially overlap the second bonding pad 830 in the horizontal direction. As used herein, “an element A overlapping an element B in a direction X” (or similar language) means that there is at least one line that extends in the direction X and intersects both the elements A and B.

Likewise, the seventh via 520 and the thirteenth wiring 530 may be disposed on the second region II of the third substrate 600, and at least partially overlap the first bonding pad structure in the third direction D3. The seventh via 520 and the thirteenth wiring 530 may be disposed at the same level as a portion of the fourth bonding pad 580 on the first region I of the third substrate 600, and at least partially overlap the second bonding pad 830 in the horizontal direction.

Second to sixth contact plugs 452, 454, 470, 474 and 476, seventh to twelfth wirings 440, 460, 480, 484, 486 and 500, a sixth via 490 and the bit line structure 430 may be disposed on the ninth insulating interlayer 540, the seventh via 520, and the fourth bonding pad 580, which may be covered by the eighth insulating interlayer 510.

The first and second gate structures and the channel 125 may be disposed on the bit line structure 430, and may extend through the fifth insulating interlayer 300 on the eighth insulating interlayer 510. The sixth insulating interlayer 170 may be disposed on the fifth insulating interlayer 300, and the first to third conductive pads 180, 184 and 186 may extend through the sixth insulating interlayer 170. In example embodiments, a plurality of first conductive pads 180 may be spaced apart from each other in the first and second directions D1 and D2.

In an example embodiment, each of the first to third conductive pads 180, 184 and 186 may include first and second conductive patterns sequentially stacked in the third direction D3. The first conductive pattern may include, e.g., doped polysilicon, and the second conductive pattern may include, e.g., a metal, a metal nitride, a metal silicide, etc.

The sixth via 490 may be disposed between the twelfth and ninth wirings 500 and 480, and may contact the twelfth and ninth wirings 500 and 480. The fourth contact plug 470 may be disposed between the ninth and eighth wirings 480 and 460, and may contact the ninth and eighth wirings 480 and 460. The fifth contact plug 474 may be disposed between the tenth wiring 484 and the second conductive pad 184, and may contact the tenth wiring 484 and the second conductive pad 184. The sixth contact plug 476 may be disposed between the eleventh wiring 486 and the third conductive pad 186, and may contact the eleventh wiring 486 and the third conductive pad 186. Each of the fifth and sixth contact plugs 474 and 476 may extend through the eighth and fifth insulating interlayers 510 and 300.

The second contact plug 452 may be disposed between the eighth wiring 460 and the bit line structure 430, and may contact the eighth wiring 460 and bit line structure 430. The third contact plug 454 may be disposed between the eighth wiring 460 and a second gate electrode 160 included in the second gate structure or a first gate electrode 140 included in the first gate structure, and may contact the eighth wiring 460 and the second gate electrode 160 included in the second gate structure or the first gate electrode 140 included in the first gate structure.

In example embodiments, each of the second to sixth contact plugs 452, 454, 470, 474 and 476 may have a width in the horizontal direction that may gradually decrease from a bottom to a top thereof with increasing distance in the third direction D3 from an upper surface of the third substrate 600.

The first gate structure may include the first gate electrode 140 and a first gate insulating pattern 130, and the second gate structure may include the second gate electrode 160 and a second gate insulating pattern 150.

In example embodiments, the first gate electrode 140 may extend in the first direction D1, and a plurality of first gate electrodes 140 may be spaced apart from each other in the second direction D2. The second gate electrode 160 may extend in the first direction D1 at a same level as the first gate electrode 140, and a plurality of second gate electrodes 160 may be spaced apart from each other in the second direction D2. In example embodiments, the first and second gate electrodes 140 and 160 may be alternately and repeatedly disposed in the second direction D2.

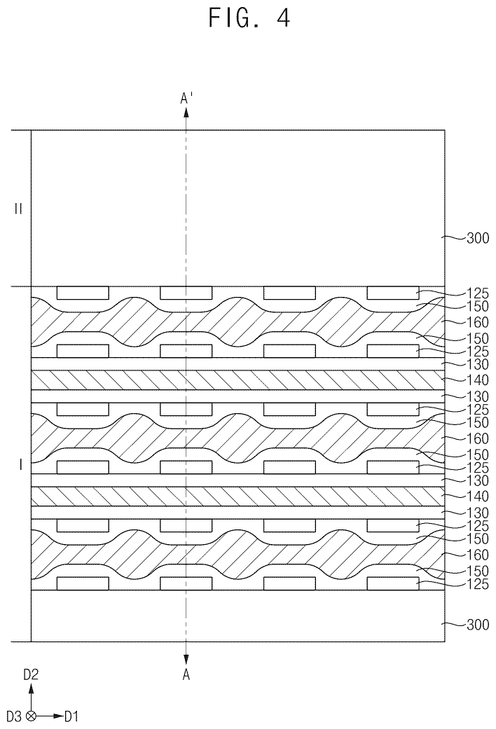

Referring to FIG. 1 together with FIG. 4, the first gate electrode 140 may have a straight bar shape extending in the first direction D1 in a plan view, while the second gate electrode 160 may include an extension portion straightly extending in the first direction D1 and protrusion portions, each of which may protrude in the second direction D2 from the extension portion, spaced apart from each other in the first direction D1; that is, the second gate electrode 160 may have a wavy contour in plan view.

Each of the first and second gate electrodes 140 and 160 may include a metal, e.g., tungsten, copper, aluminum, etc.

In example embodiments, the second gate electrode 160 may serve as a word line of the semiconductor device, and the first gate electrode 140 may serve as a back gate electrode of the semiconductor device. However, the inventive concept is not limited thereto. For example, the first gate electrode 140 may serve as the word line of the semiconductor device, and the second gate electrode 160 may serve as the back gate electrode of the semiconductor device.

In example embodiments, the first gate insulating pattern 130 may be disposed on the eighth insulating interlayer 510 and the bit line structure 430, and may extend in the first direction D1 and cover an upper surface and a sidewall of the first gate electrode 140. The second gate insulating pattern 150 may be disposed on the eighth insulating interlayer 510 and the bit line structure 430, and may extend in the first direction D1 and cover an upper surface and a sidewall of the second gate electrode 160. A cross-section in the second direction D2 of each of the first and second gate insulating patterns 130 and 150 may have, e.g., a reversed cup shape.

As the first and second gate electrodes 140 and 160 are alternately and repeatedly disposed in the second direction D2, the first and second gate insulating patterns 130 and 150 may also be alternately and repeatedly disposed in the second direction D2.

In example embodiments, each of opposite sidewalls in the second direction D2 of the first gate insulating pattern 130 may have a shape of a straight line extending in the first direction D1 in a plan view, while each of opposite sidewalls in the second direction D2 of the second gate insulating pattern 150 may have a zigzag pattern in a plan view. Each of the first and second gate insulating patterns 130 and 150 may include an oxide, e.g., silicon oxide.

The channel 125 may be disposed on an outer sidewall of the first gate insulating pattern 130 in the second direction D2 on each of the bit line structures 430 extending in the second direction D2, and a plurality of channels 125 may be spaced apart from each other in the second direction D2. A first sidewall in the second direction D2 of each of the channels 125 may contact the outer sidewall in the second direction D2 of the first gate insulating pattern 130, and a second sidewall in the second direction D2 and opposite sidewalls in the first direction D1 of each of the channels 125 may contact an outer sidewall in the second direction D2 of the second gate insulating pattern 150.

In example embodiments, the channel 125 may include a semiconductor material, e.g., silicon, germanium, silicon-germanium, etc. Alternatively, the channel 125 may include an oxide semiconductor material, e.g., indium gallium zinc oxide (IGZO).

The capacitor 220 may include first and second capacitor electrodes 190 and 210 and a dielectric layer 200 between the first and second capacitor electrodes 190 and 210. The first capacitor electrode 190 may contact an upper surface of the first conductive pad 180, and may extend in the third direction D3. A plurality of first capacitor electrodes 190 may be spaced apart from each other in the first and second directions D1 and D2. In example embodiments, the first capacitor electrode 190 may be arranged in a lattice pattern or a honeycomb pattern in a plan view.

A support layer 320 and a first etch stop layer 310 may be disposed on a sidewall of each of the first capacitor electrodes 190. The first etch stop layer 310 may be disposed on a lowermost sidewall of each of the first capacitor electrodes 190, and a plurality of support layers 320 may be spaced apart from each other in the third direction D3 on the sidewall of each of the first capacitor electrodes 190.

The dielectric layer 200 may be disposed on the sidewall of the first capacitor electrode 190, upper and lower surfaces and a sidewall of the support layer 320, and an upper surface and a sidewall of the first etch stop layer 310. The second capacitor electrode 210 may be disposed between ones of the support layers 320 adjacent in the third direction D3 and between the first etch stop layer 310 and a lowermost one of the support layers 320. The dielectric layer 200 may cover upper and lower surfaces and a sidewall of the second capacitor electrode 210.

The plate electrode 230 may be disposed on the sixth insulating interlayer 170, and may cover an upper surface and a sidewall of the capacitor 220.

Each of the first and second capacitor electrodes 190 and 210 may include, e.g., a metal, a metal nitride, a metal silicide, etc., and the dielectric layer 200 may include a high-k material, e.g., metal oxide. The support layer 320 may include an insulating nitride, e.g., silicon nitride, and the first etch stop layer 310 may include an insulating nitride, e.g., silicon boron nitride. The plate electrode 230 may include, e.g., doped silicon-germanium, or a metal such as tungsten.

The seventh insulating interlayer 330 may be disposed on the sixth insulating interlayer 170, and may cover the capacitor 220 and the plate electrode 230. A second etch stop layer 840 may be disposed on the seventh insulating interlayer 330, and a fourteenth wiring 860 may be disposed on the second etch stop layer 840. The eleventh insulating interlayer 870 may be disposed on the second etch stop layer 840, and may cover a sidewall of the fourteenth wiring 860.

A seventh contact plug 852 may extend through the second etch stop layer 840 and an upper portion of the seventh insulating interlayer 330, and may contact an upper surface of the plate electrode 230. Eighth and ninth contact plugs 854 and 856 may extend through the second etch stop layer 840 and the seventh insulating interlayer 330, and may contact upper surfaces of the second and third conductive pads 184 and 186, respectively.

Each of the first to fourteenth wirings 660, 680, 700, 720, 740, 780, 440, 460, 484, 486, 500, 530 and 860, each of the first to seventh vias 670, 690, 710, 730, 770, 490 and 520, and each of the first to ninth contact plugs 650, 452, 454, 470, 474, 476, 852, 854 and 856 may include a conductive material, e.g., a metal, a metal nitride, a metal silicide, etc. Each of the first to eleventh insulating interlayers 750, 760, 790, 800, 300, 170, 330, 510, 540, 550 and 870 may include an oxide, e.g., silicon oxide, and in some embodiments, may be merged with each other.

In the semiconductor device, currents may flow in the channel 125 extending in the third direction D3, which is vertical direction, between the bit line structure 430 and the first conductive pad 180, and thus the semiconductor device may be a vertical channel transistor (VCT) DRAM device that may include a vertical channel transistor having a vertical channel.

In the semiconductor device, the fifth via 770 and the sixth wiring 780 may be disposed under the first bonding pads 820, and at least partially overlap the second bonding pads 830 in the vertical direction on the second region II of the third substrate 600. The fifth via 770 and the sixth wiring 780 may be disposed on the third bonding pads 570, at least partially overlap the fourth bonding pad 580 in the horizontal direction, contact the twelfth wiring 500, and electrically connected to the twelfth wiring 500 on the second region II of the third substrate 600.

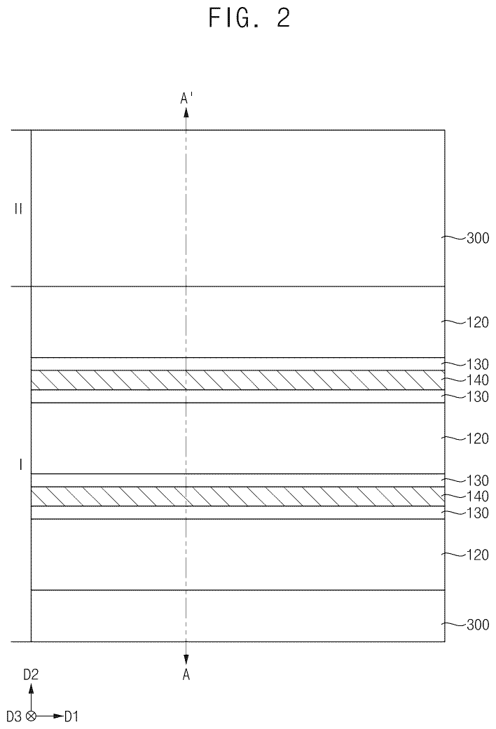

Thus, as illustrated below with reference to FIGS. 2 to 18, a portion of the wiring structure may be formed in a space over and/or under the first and third bonding pads 820 and 570, which may be used to prevent a dishing phenomenon during a planarization process on the second and fourth bonding pads 830 and 580 electrically connected to the wiring structure, so that a degree of freedom of a layout of the wiring structure may be increased, and an integration degree of the semiconductor device including the wiring structure may be increased.

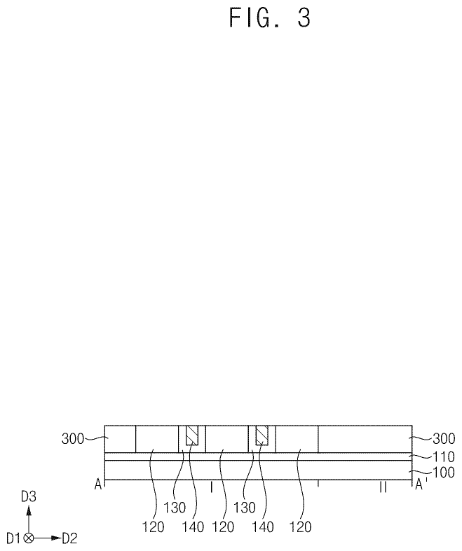

FIGS. 2 to 18 are schematic plan views and schematic cross-sectional views illustrating intermediate processes in a method of manufacturing a semiconductor device in accordance with example embodiments. Specifically, FIGS. 2, 4 and 6 are the schematic plan views, and FIGS. 3, 5 and 7-18 are schematic cross-sectional views taken along lines A-A′ of corresponding plan views, respectively.

Referring to FIGS. 2 and 3, a first substrate structure including a first bulk substrate 100, a buried oxide layer 110 and a second bulk substrate may be provided, and the second bulk substrate may be patterned to form a preliminary channel 120.

The first substrate structure may include first and second regions I and II.

In example embodiments, the preliminary channel 120 may extend in the first direction D1, and a plurality of preliminary channels 120 may be spaced apart from each other in the second direction D2. A first opening may be formed between ones of the preliminary channels 120 adjacent in the second direction D2 to expose an upper surface of the buried oxide layer 110. The term “expose” (or “exposed,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device.

A first gate insulating layer may be formed on the preliminary channel 120 and the buried oxide layer 110, an anisotropic etching process may be performed on the first gate insulating layer to remove a portion of the first gate insulating layer on an upper surface of the preliminary channel 120. Thus, a first gate insulating pattern 130 may be formed on a sidewall of the first opening and the upper surface of the buried oxide layer 110. In example embodiments, the first gate insulating pattern 130 may contact opposite sidewalls in the second direction D2 of respective ones of the preliminary channels 120 adjacent in the second direction D2 and an upper surface of a portion of the buried oxide layer 110 between the adjacent (i.e., neighboring) ones of the preliminary channels 120, and may extend in the first direction D1.

A first gate electrode layer may be formed on the preliminary channel 120 and the first gate insulating pattern 130, and a planarization process may be performed on the first gate electrode layer until the upper surface of the preliminary channel 120 and an upper surface of the first gate insulating pattern 130 are exposed to form a first gate electrode 140. The planarization process may include, e.g., a chemical mechanical polishing (CMP) process and/or an etch back process, although embodiments are not limited thereto.

The first gate electrode 140 and the first gate insulating pattern 130 may collectively form a first gate structure. The first gate structure may extend in the first direction D1, and a plurality of first gate structures may be spaced apart from each other in the second direction D2.

Portions of the preliminary channel 120, the first gate insulating pattern 130 and the first gate electrode 140 on the second region II of the first substrate structure may be removed to form a second opening exposing the upper surface of the buried oxide layer 110, and a fifth insulating interlayer 300 may be formed in the second opening.

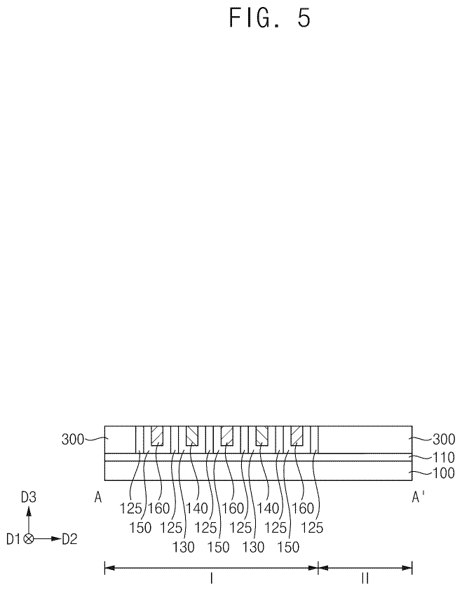

Referring to FIGS. 4 and 5, the preliminary channel 120 may be patterned to form a channel 125.

In example embodiments, a plurality of channels 125 may be spaced apart from each other in the first direction D1 on a sidewall in the second direction D2 of the first gate insulating pattern 130 extending in the first direction D1. A third opening may be formed between ones of the channels 125 that are disposed between ones of the first gate insulating patterns 130 neighboring in the second direction D2, and may expose the upper surface of the buried oxide layer 110.

A second gate insulating layer may be formed on the channel 125, the first gate insulating pattern 130, the first gate electrode 140 and the buried oxide layer 110, and a portion of the second gate insulating layer on an upper surface of the channel 125, the upper surface of the first gate insulating pattern 130 and an upper surface of the first gate electrode 140 may be removed by, e.g., an anisotropic etching process to form a second gate insulating pattern 150.

In example embodiments, the second gate insulating pattern 150 may contact opposite sidewalls in the second direction D2 of ones of the first gate insulating patterns 130 neighboring in the second direction D2, opposite sidewalls in the second direction D2 of ones of the channels 125 neighboring in the second direction D2, an upper surface of a portion of the buried oxide layer 110 between the neighboring ones of the first gate insulating patterns 130 and an upper surface of a portion of the buried oxide layer 110 between the neighboring ones of the channels 125.

A second gate electrode layer may be formed on the channel 125, the first and second gate insulating patterns 130 and 150, the first gate electrode 140 and the fifth insulating interlayer 300, and a planarization process may be performed on the second gate electrode layer until the upper surfaces of the channel 125, the first gate insulating pattern 130 and the first gate electrode 140, and upper surfaces of the second gate insulating pattern 150 and the fifth insulating interlayer 300 are exposed to form a second gate electrode 160. The planarization process may include a CMP process and/or an etch back process.

The second gate electrode 160 and the second gate insulating pattern 150 may collectively form a second gate structure. The second gate structure may extend in the first direction D1, and a plurality of second gate structures may be spaced apart from each other in the second direction D2.

In example embodiments, the second gate electrode 160 may include an extension portion straightly extending in the first direction D1 and protrusion portions that may protrude from the extension portion in the second direction D2 and be spaced apart from each other in the first direction D1, in a plan view.

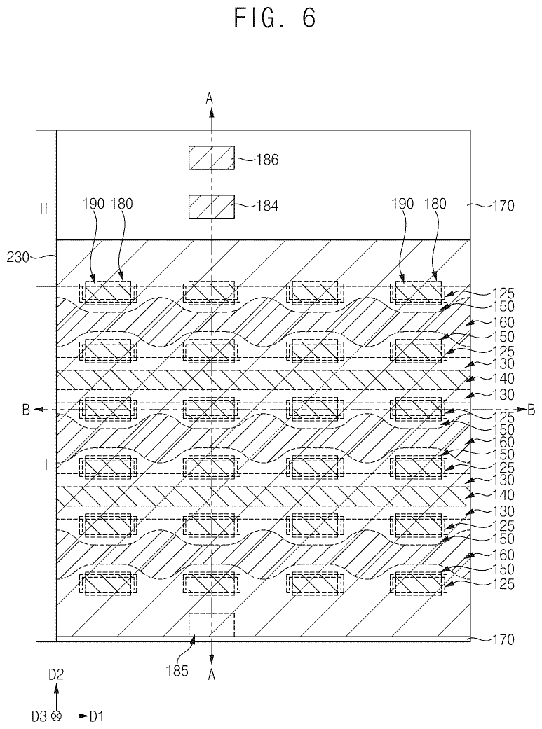

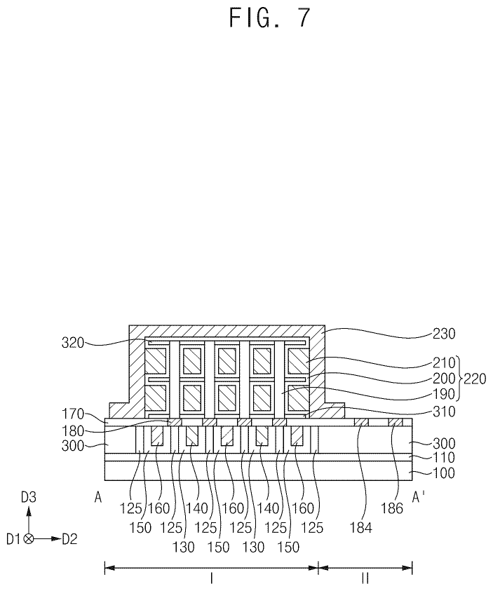

Referring to FIGS. 6 and 7, a sixth insulating interlayer 170 may be formed on the first and second gate structures and the fifth insulating interlayer 300, and first to third conductive pads 180, 184 and 186 may be formed through the sixth insulating interlayer 170.

In example embodiments, a plurality of first conductive pads 180 may be spaced apart from each other in each of the first and second directions D1 and D2 to contact upper surfaces of corresponding ones of the channels 125, respectively. The second and third conductive pads 184 and 186 may be formed through a portion of the sixth insulating interlayer 170 on the fifth insulating interlayer 300.

A capacitor 220 and a plate electrode 230 may be formed on the sixth insulating interlayer 170 and the first conductive pad 180. The capacitor 220 and the plate electrode 230 may be formed by, e.g., following processes.

A first etch stop layer 310 may be formed on the sixth insulating interlayer 170 and the first to third conductive pads 180, 184 and 186, and a mold layer and a support layer 320 may be alternately and repeatedly formed on the first etch stop layer 310. The first etch stop layer 310 may include an insulating nitride, e.g., silicon boronitride, the mold layer may include an oxide, e.g., silicon oxide, and the support layer 320 may include an insulating nitride, e.g., silicon nitride.

A fourth opening may be formed through the support layer 320, the mold layer and the first etch stop layer 310 to expose an upper surface of the first conductive pad 180, a first capacitor electrode layer may be formed on the upper surface of the first conductive pad 180 exposed by the fourth opening and an upper surface of an uppermost one of the support layers 320, and a planarization process may be performed on the first capacitor electrode layer until the upper surface of the uppermost one of the support layers 320 is exposed to form a first capacitor electrode 190 in the fourth opening.

The planarization process may include, e.g., a CMP process and/or an etch back process.

The support layer 320 and the mold layer may be partially removed to form a fifth opening exposing an upper surface of the first etch stop layer 310, and the mold layer may be removed through the fifth opening.

In example embodiments, the mold layer may be removed by a wet etching process, and as the wet etching process is performed, a sixth opening may be formed to expose a sidewall of the first capacitor electrode 190 and the upper surface of the first etch stop layer 310. However, the support layers 320 may remain on the sidewall of each of the first capacitor electrodes 190, and thus a surface of each of the support layers 320 may be exposed by the sixth opening.

A dielectric layer 200 may be formed on the sidewall of each of the first capacitor electrodes 190, the upper surface of the first etch stop layer 310 and the surface of each of the support layers 320 exposed by the sixth opening, and a second capacitor electrode layer may be formed on the dielectric layer 200 to fill the sixth opening. The term “fill” (or “fills,” or like terms) is intended to refer to either completely filling a defined space (e.g., the sixth opening) or partially filling the defined space; that is, the defined space need not be entirely filled but may, for example, be partially filled or have voids or other spaces throughout. The dielectric layer 200 and the second capacitor electrode layer may also be formed on an upper surface of the first capacitor electrode 190 and the upper surface of the uppermost one of the support layers 320.

For example, a wet etching process may be performed on the second capacitor electrode layer to form a second capacitor electrode 210 in the sixth opening. The first capacitor electrode 190, the dielectric layer 200 and the second capacitor electrode 210 may collectively form a capacitor 220.

A plate electrode 230 may be formed on an upper surface and a sidewall of the capacitor 220 and an upper surface of the sixth insulating interlayer 170.

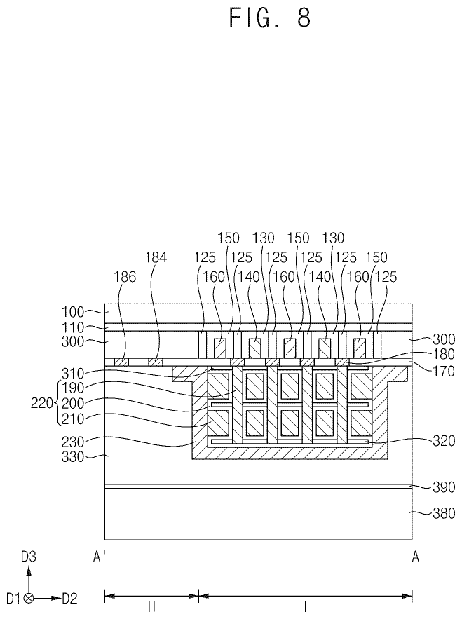

Referring to FIG. 8, a seventh insulating interlayer 330 may be formed on the sixth insulating interlayer 170 and the second and third conductive pads 184 and 186 to cover the plate electrode 230, and a second substrate 380 may be bonded with an upper surface of the seventh insulating interlayer 330 via a temporary bonding layer 390 therebetween.

The second substrate 380 may also include first and second regions I and II that may be aligned in the third direction D3 with those of the first substrate structure. The second substrate 380 may include a semiconductor material, e.g., silicon, or an insulating material, e.g., glass, and the temporary bonding layer 390 may include, e.g., silicon carbonitride, silicon oxide, etc.

The second substrate 380 may be flipped, and top and bottom of structures on the second substrate 380 may be reversed. Thus, following explanation is based on the reversed direction.

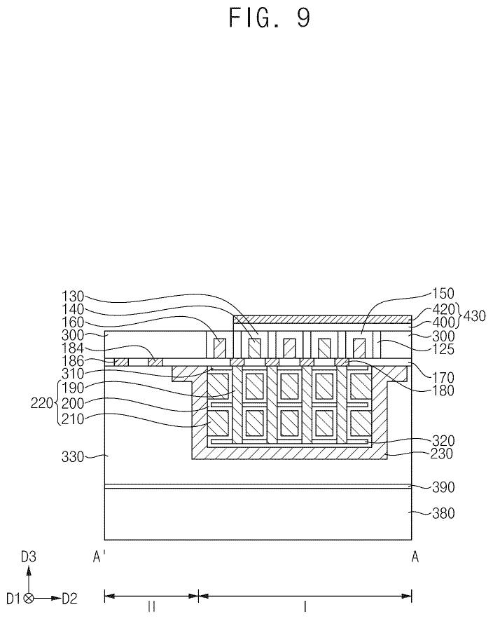

Referring to FIG. 9, the first bulk substrate 100 and the buried oxide layer 110 included in the first substrate structure (see FIG. 8) may be removed by, e.g., a grinding process, and thus upper surfaces of the channel 125, the first and second gate insulating patterns 130 and 150 and the fifth insulating interlayer 300 may be exposed.

A bit line structure 430 may be formed on the upper surfaces of the channel 125, the first and second gate insulating patterns 130 and 150 and the first insulating interlayer 300. In example embodiments, the bit line structure 430 may extend in the second direction D2, and a plurality of bit line structures 430 may be spaced apart from each other in the first direction D1. Each of the bit line structures 430 may contact the upper surfaces of ones of the channels 125 that are disposed in the second direction D2.

In an example embodiment, each of the bit line structures 430 may include third and fourth conductive patterns 400 and 420 stacked in the third direction D3, which may include, e.g., doped polysilicon and a metal, respectively.

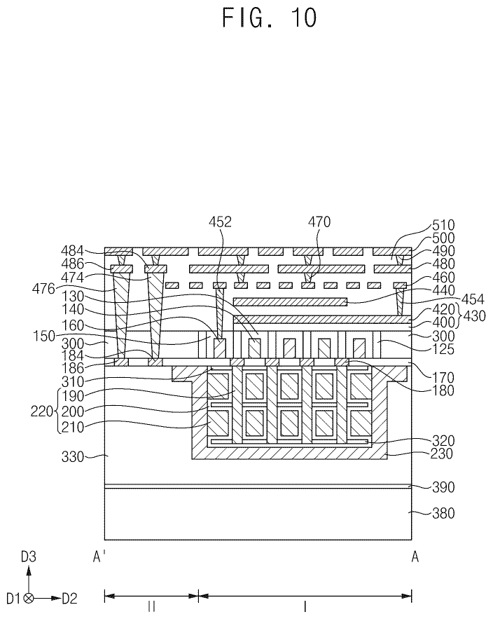

Referring to FIG. 10, second to sixth contact plugs 452, 454, 470, 474 and 476, seventh to twelfth wirings 440, 460, 480, 484, 486 and 500, and a sixth via 490 may be formed on the bit line structure 430, and an eighth insulating interlayer 510 may be formed on the channel 125, the first and second gate insulating patterns 130 and 150, and the fifth insulating interlayer 300 to cover the second to sixth contact plugs 452, 454, 470, 474 and 476, the seventh to twelfth wirings 440, 460, 480, 484, 486 and 500, and the sixth via 490.

In example embodiments, each of the second to sixth contact plugs 452, 454, 470, 474 and 476 may be formed to have a width in the horizontal direction that gradually decreases from a top to a bottom thereof with decreasing distance in the third direction D3 to an upper surface of the second substrate 380, due to the characteristics of etching processes for forming the second to sixth contact plugs 452, 454, 470, 474 and 476.

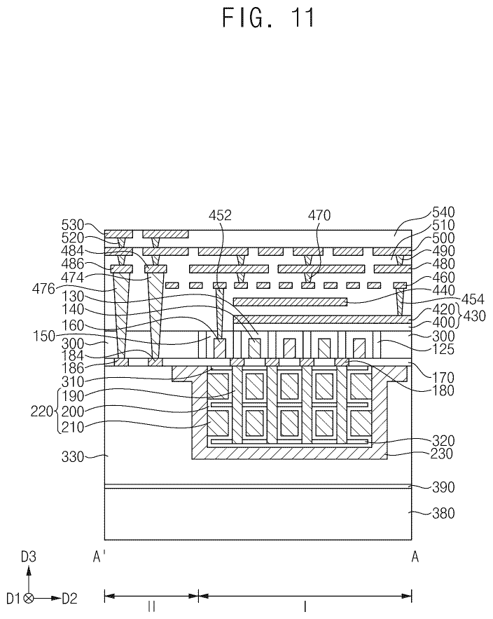

Referring to FIG. 11, a seventh via 520 may be formed on the second region II of the second substrate 380 to contact an upper surface of the twelfth wiring 500, a thirteenth wiring 530 may be formed on the seventh via 520, and a ninth insulating interlayer 540 may be formed on the eighth insulating interlayer 510 and twelfth wiring 500 to cover the seventh via 520 and the thirteenth wiring 530.

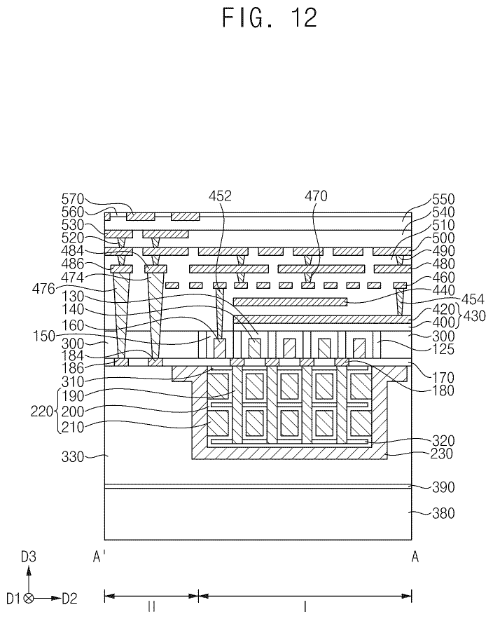

Referring to FIG. 12, a tenth insulating interlayer 550 and a second bonding layer 560 may be sequentially formed on the ninth insulating interlayer 540 and the thirteenth wiring 530, and a third bonding pad 570 may be formed through the second bonding layer 560 and an upper portion of the tenth insulating interlayer 550 on the second region II of the second substrate 380.

In example embodiments, the third bonding pad 570 may be formed by forming a first trench through the second bonding layer 560 and the upper portion of the tenth insulating interlayer 550, forming a third boning pad layer in the first trench, and performing a planarization process, e.g., a CMP process on the third bonding pad layer until an upper surface of the second bonding layer 560 is exposed.

In example embodiments, the second bonding layer 560 may include, e.g., silicon carbonitride, and the third bonding pad 570 may include, e.g., copper.

In example embodiments, a plurality of first trenches may be spaced apart from each other in the horizontal direction on the second region II of the second substrate 380. In some embodiments, during the planarization process on the third bonding pad layer, a recess may be formed on upper surfaces of the third bonding pads 570 in the first trenches and upper surfaces of portions of the second bonding layer 560 adjacent to the third bonding pads 570, by a dishing phenomenon due to a density difference between the second region II of the second substrate 380 on which the first trenches are formed and the first region I of the second substrate 380 on which the first trenches are not be formed.

As the plurality of first trenches are spaced apart from each other, a plurality of third bonding pads 570, which may be formed in the first trenches, respectively, may also be spaced apart from each other in the horizontal direction, and each of the third bonding pads 570 may have a third thickness in the third direction D3.

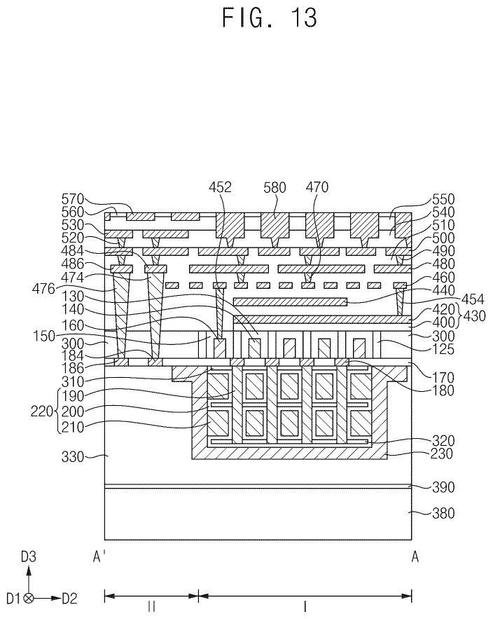

Referring to FIG. 13, a fourth bonding pad 580 may be formed through the second bonding layer 560, the tenth insulating interlayer 550 and the ninth insulating interlayer 540 on the first region I of the second substrate 380 to contact an upper surface of the twelfth wiring 500.

In example embodiments, the fourth bonding pad 580 may be formed by forming a second trench through the second bonding layer 560, the tenth insulating interlayer 550 and an upper portion of the ninth insulating interlayer 540, forming a first via hole through a lower portion of the ninth insulating interlayer 540 to be connected to the second trench, forming a fourth bonding pad layer in the second trench and the first via hole, and performing a planarization process, e.g., a CMP process on the fourth bonding pad layer until an upper surface of the second bonding layer 560 is exposed.

Thus, the fourth bonding pad 580 may include a lower portion in the first via hole and an upper portion that may be disposed on the lower portion in the second trench, and the upper portion of the fourth bonding pad 580 may have a horizontal width greater than that of the lower portion of the fourth bonding pad 580.

In example embodiments, the fourth bonding pad 580 may include, e.g., copper.

In example embodiments, a plurality of second trenches may be spaced apart from each other in the horizontal direction on the first region I of the second substrate 380, and a plurality of first via holes may be spaced apart from each other in the horizontal direction on the first region I of the second substrate 380. Thus, a plurality of fourth bonding pads 580, each of which may be formed in the second trench and the first via hole, may also be spaced apart from each other in the horizontal direction on the first region I of the second substrate 380.

The third bonding pads 570 have already been formed on the second region II of the second substrate 380 on which the second trenches and the first via holes are not formed, so that a recess by a dishing phenomenon may not be formed on upper surfaces of the fourth bonding pads 580, during the planarization process on the fourth bonding pad layer.

Each of the fourth bonding pads 580 may have a fourth thickness in the third direction D3 greater than the third thickness, and a thickness in the third direction D3 of the upper portion of the fourth bonding pad 580 may be greater than the third thickness.

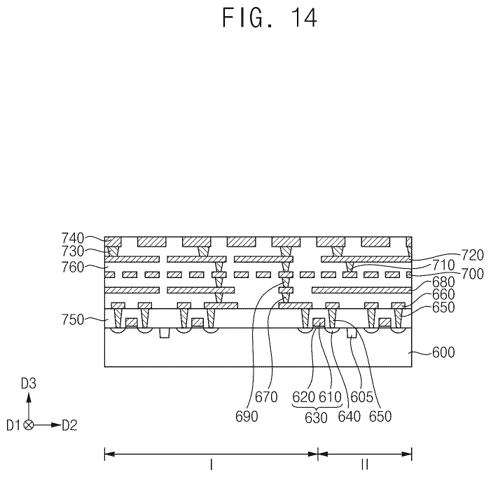

Referring to the FIG. 14, a third gate structure 630 may be formed on a third substrate 600, and impurity regions 640 may be formed in upper portions, respectively, of the third substrate 600 adjacent to the third gate structure 630, so that a transistor may be formed to include the third gate structure 630 and the impurity regions 640.

The third substrate 600 may also include first and second regions I and II, and a plurality of transistors may be spaced apart from each other in the horizontal direction in the first and second regions I and II of the third substrate 600.

A first insulating interlayer 750 may be formed on the third substrate 600 to cover the transistors, and a first contact plug 650 may be formed through the first insulating interlayer 750 to contact an upper surface of the impurity region 640.

First to fourth vias 670, 690, 710 and 730, and first to fifth wirings 660, 680, 700, 720 and 740 may be formed on the first insulating interlayer 750 and first contact plug 650, and a second insulating interlayer 760 may be formed on the first insulating interlayer 750 to cover the first to fourth vias 670, 690, 710 and 730, and the first to fifth wirings 660, 680, 700, 720 and 740.

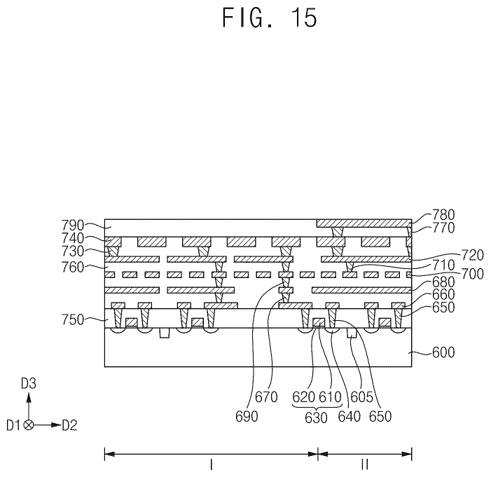

Referring to FIG. 15, a fifth via 770 may be formed to contact an upper surface of the fifth wiring 740 on the second region II of the third substrate 600, a sixth wiring 780 may be formed on the fifth via 770, and a third insulating interlayer 790 may be formed on the second insulating interlayer 760 and the sixth wiring 780 to cover the fifth via 770 and the sixth wiring 780.

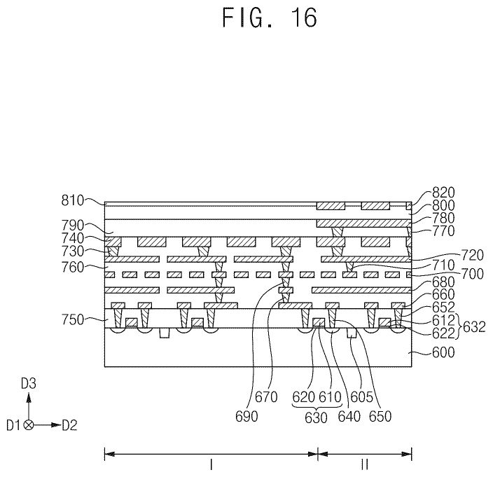

Referring to FIG. 16, a fourth insulating interlayer 800 and a first bonding layer 810 may be sequentially formed on the third insulating interlayer 790 and the sixth wiring 780, and a first bonding pad 820 may be formed through the first bonding layer 810 and an upper portion of the fourth insulating interlayer 800 on the second region II of the third substrate 600.

In example embodiments, the first bonding pad 820 may be formed by forming a third trench through the first bonding layer 810 and the upper portion of the fourth insulating interlayer 800, forming a first boning pad layer in the third trench, and performing a planarization process, e.g., a CMP process on the first bonding pad layer until an upper surface of the first bonding layer 810 is exposed.

In example embodiments, the first bonding layer 810 may include, e.g., silicon carbonitride, and the first bonding pad 820 may include, e.g., copper.

In example embodiments, a plurality of third trenches may be spaced apart from each other in the horizontal direction on the second region II of the third substrate 600. In some embodiments, during the planarization process on the first bonding pad layer, a recess may be formed on upper surfaces of the first bonding pads 820 in the third trenches and upper surfaces of portions of the first bonding layer 810 adjacent to the first bonding pads 820, by a dishing phenomenon due to a density difference between the second region II of the third substrate 600 on which the third trenches are formed and the first region I of the third substrate 600 on which the third trenches are not be formed.

As the plurality of third trenches are spaced apart from each other, a plurality of first bonding pads 820, which may be formed in the third trenches, respectively, may also be spaced apart from each other in the horizontal direction, and each of the first bonding pads 820 may have a first thickness in the third direction D3.

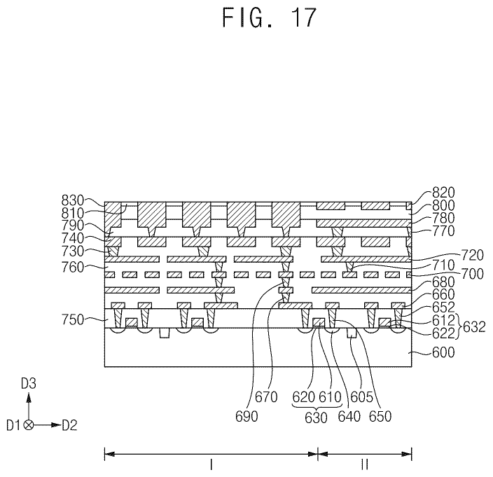

Referring to FIG. 17, a second bonding pad 830 may be formed through the first bonding layer 810, the fourth insulating interlayer 800 and the third insulating interlayer 790 to contact an upper surface of the fifth wiring 740 on the first region I of the third substrate 600.

In example embodiments, the second bonding pad 830 may be formed by forming a fourth trench through the first bonding layer 810, the fourth insulating interlayer 800 and an upper portion of the third insulating interlayer 790, forming a second via hole through a lower portion of the third insulating interlayer 790 to be connected to the fourth trench, forming a second bonding pad layer in the fourth trench and the second via hole, and performing a planarization process, e.g., a CMP process on the second bonding pad layer until an upper surface of the first bonding layer 810 is exposed.

Thus, the second bonding pad 830 may include a lower portion in the second via hole and an upper portion that may be disposed on the lower portion in the fourth trench, and the upper portion of the second bonding pad 830 may have a width greater than that of the lower portion of the second bonding pad 830.

In example embodiments, the second bonding 830 pad may include, e.g., copper.

In example embodiments, a plurality of fourth trenches may be spaced apart from each other in the horizontal direction on the first region I of the third substrate 600, and a plurality of the second via holes may be spaced apart from each other in the horizontal direction on the first region I of the third substrate 600. Thus, a plurality of second bonding pads 830, each of which may be formed in the fourth trench and the second via hole, may also be spaced apart from each other in the horizontal direction.

The first bonding pads 820 have already been formed on the second region II of the third substrate 600 on which the fourth trenches and the second via holes are not formed, so that a recess by a dishing phenomenon may not be formed on upper surfaces of the second bonding pads 830, during the planarization process on the second bonding pad layer.

Each of the second bonding pads 830 may have a second thickness in the third direction D3 greater than the first thickness in the third direction D3, and a thickness in the third direction D3 of each of the upper portion of the second bonding pad 830 may be greater than the first thickness.

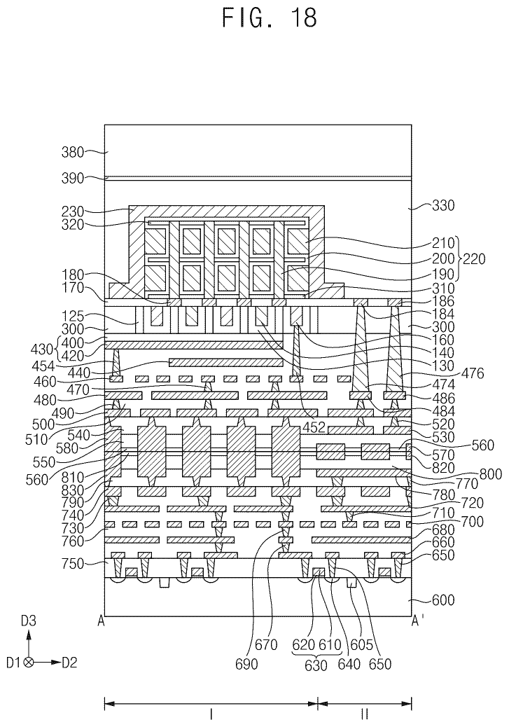

Referring to FIG. 18, structures illustrated in FIG. 13 may be bonded with structures illustrated in FIG. 17.

Particularly, the second substrate 380 may be flipped, a structure under the second substrate 380 and a structure on the third substrate 600 may be bonded with each other, so that the first and second regions I and II of the second substrate may overlap the first and second regions I and II, respectively, of the third substrate 600 in the third direction D3. The first and second bonding layers 810 and 560 may be bonded to each other to form a bonding layer structure, the first and third bonding pads 820 and 570 may be bonded to each other to form a first bonding pad structure, and the second and fourth bonding pads 830 and 580 may be bonded to each other to form a second bonding layer structure.

Referring to FIG. 1 again, the temporary bonding layer 390 and the second substrate 380 may be removed from the seventh insulating interlayer 330, a second etch stop layer 840 may be formed on the seventh insulating interlayer 330, a seventh contact plug 852 may be formed through the second etch stop layer 840 and an upper portion of the seventh insulating interlayer 330 to contact an upper surface of a plate electrode 230, and eighth and ninth contact plugs 854 and 856 may be formed through the second etch stop layer 840 and the seventh insulating interlayer 330 to contact upper surfaces of the second and third conductive pads 184 and 186, respectively.

A fourteenth wiring 860 may be formed on the second etch stop layer 840 to contact upper surfaces of the seventh to ninth contact plugs 852, 854 and 856, and an eleventh insulating interlayer 870 may be formed on the second etch stop layer 840 to cover a sidewall of the fourteenth wiring 860, so that the fabrication of the semiconductor device may be completed.

As described above, the structure on the second substrate 380 and the structure on the third substrate 600 may be bonded to each other by a hybrid copper bonding (HCB) process using the first and second bonding layers 810 and 560, and the first to fourth bonding pads 820, 830, 570 and 580.

When the second bonding pads 830 are formed by the planarization process on the first region I of the third substrate 600 to be electrically connected to the adjacent (i.e., neighboring) wiring structure, the first bonding pads 820 exist on the second region II of the third substrate 600, so that a recess by a dishing phenomenon may not be formed on the upper surfaces of the second bonding pads 830.

The fifth via 770 and the sixth wiring 780, which may at least partially overlap the first bonding pads 830 in the horizontal direction, may be formed under the first bonding pads 820 having a thickness smaller than that of the second bonding pads 830, and may be electrically connected to the fifth wiring 740.

The first bonding pads 820 may be formed in order to prevent the dishing phenomenon due to the density difference between the first and second regions I and II during the planarization process, and may not be connected to the neighboring wiring structure, so that the thickness in the third direction D3 of the first bonding pads 820 may be smaller than that of the second bonding pads 830 that are electrically connected to the neighboring wiring structure. Thus, a space for a portion of the wiring structure may be provided under the first bonding pads 820, so that the fifth via 770 and the sixth wiring 780, which may be portions of the wiring structure, may be disposed in the space. Accordingly, a degree of freedom of a layout of the wiring structure may be increased, and an integration degree of the semiconductor device including the wiring structure may be increased.

Likewise, the seventh via 520 and the thirteenth wiring 530 may be formed on the third bonding pads 570 to be electrically connected to the twelfth wiring 500 and at least partially overlap the fourth bonding pads 580 in the horizontal direction. Thus, the degree of freedom of the layout of the wiring structure may be increased, and the integration degree of the semiconductor device may be increased.

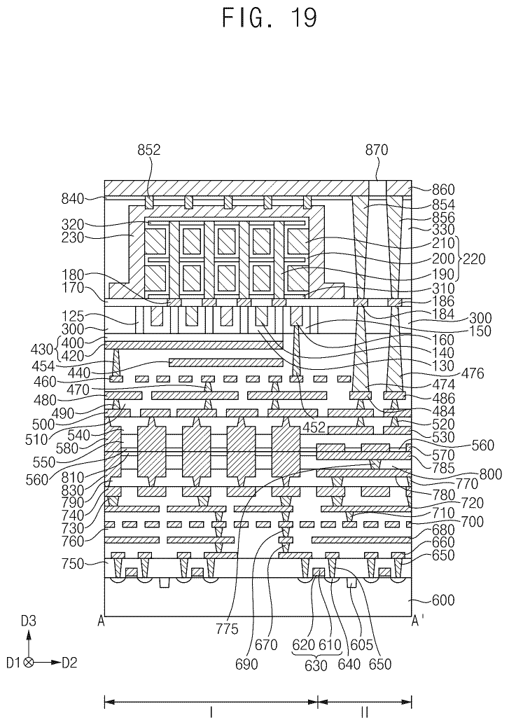

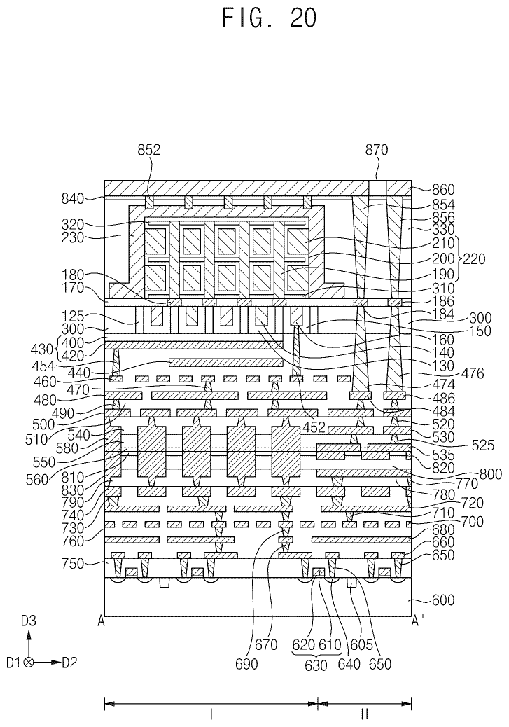

FIGS. 19 and 20 are schematic cross-sectional views illustrating semiconductor devices in accordance with example embodiments, which may correspond to FIG. 1. These semiconductor devices may be substantially the same as or similar to that of FIG. 1 except for some elements, and thus repeated explanations are omitted herein.

Referring to FIG. 19, the semiconductor device may not include the first bonding pad on the second region II of the third substrate 600, and may include an eighth via 775 and a fifteenth wiring 785 instead.

In example embodiments, the eighth via 775 may contact an upper surface of the sixth wiring 780 and be electrically connected to the sixth wiring 780. Thus, unlike the first bonding pad 820, the fifteenth wiring 785 may be electrically connected to the wiring structure.

The fifteenth wiring 785 may extend through the first bonding layer 810 and the upper portion of the fourth insulating interlayer 800, and an upper surface of the fifteenth wiring 785 may contact a lower surface of the third bonding pad 570. Thus, like the first bonding pad 820, the fifteenth wiring 785 may be bonded to the third bonding pad 570, and the fifteenth wiring 785 together with the second bonding pad 830 may bond structures disposed over and under the fifteenth wiring 785 and the second bonding pad 830.

Referring to FIG. 20, the semiconductor device may not include the third bonding pad 570 on the second region II of the third substrate 600, and may include a ninth via 525 and a sixteenth wiring 535 instead.

In example embodiments, the ninth via 525 may contact an upper surface of the thirteenth wiring 530 and electrically connected to the thirteenth wiring 530. Thus, unlike the third bonding pad 570, the sixteenth wiring 535 may be electrically connected to the wiring structure.

The sixteenth wiring 535 may extend through the second bonding layer 560 and the lower portion of the tenth insulating interlayer 550, and an upper surface of the sixteenth wiring 535 may contact an upper surface of the first bonding pad 820. Thus, like the third bonding pad 570, the sixteenth wiring 535 may be bonded to the first bonding pad 820, and the sixteenth wiring 535 together with the fourth bonding pad 580 may bond structures disposed over and under the sixteenth wiring 535 and the fourth bonding pad 580.

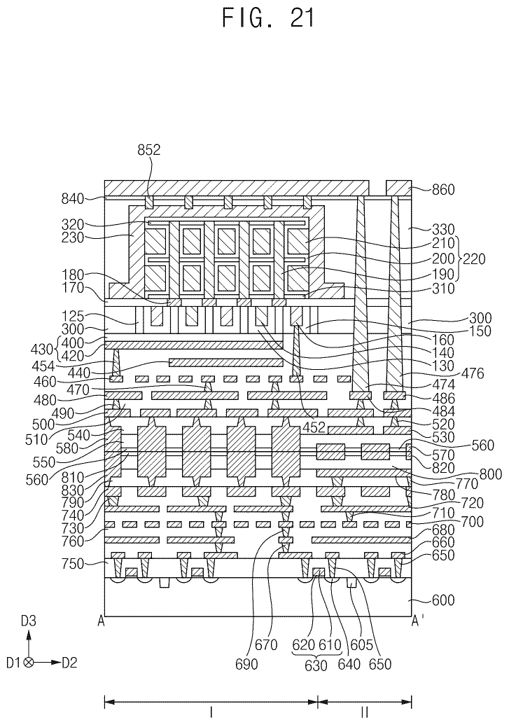

FIG. 21 is a schematic cross-sectional view illustrating a semiconductor device in accordance with example embodiments, which may correspond to FIG. 1. This semiconductor device may be substantially the same as or similar to that of FIG. 1 except for some elements, and thus repeated explanations are omitted herein.

Referring to FIG. 21, the semiconductor device may not include the eighth and ninth contact plugs 854 and 856, the second and third conductive pads 184 and 186, and the eleventh insulating interlayer 870.

In example embodiments, each of the fifth and sixth contact plugs 474 and 476 may extend through the eighth insulating interlayer 510, the fifth insulating interlayer 300, the sixth insulating interlayer 170, the seventh insulating interlayer 330 and the second etch stop layer 840, and may contact upper surfaces of the tenth and eleventh wirings 484 and 486, respectively, and a lower surface of the fourteenth wiring 860. Each of the fifth and sixth contact plugs 474 and 476 may have a width in the horizontal direction that gradually increases from a bottom to a top thereof with decreasing distance to the upper surface of the third substrate 600 in the third direction D3.

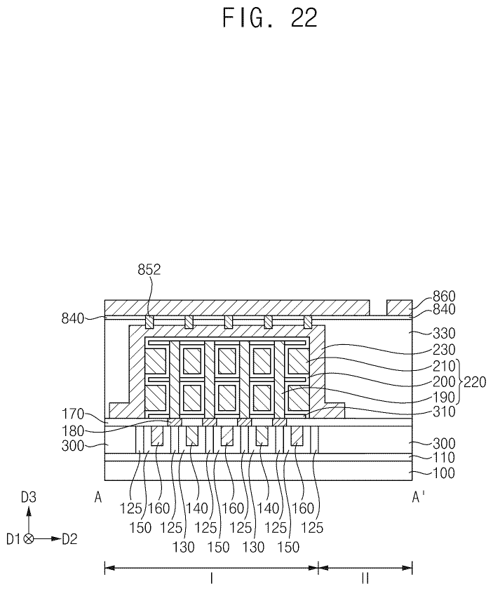

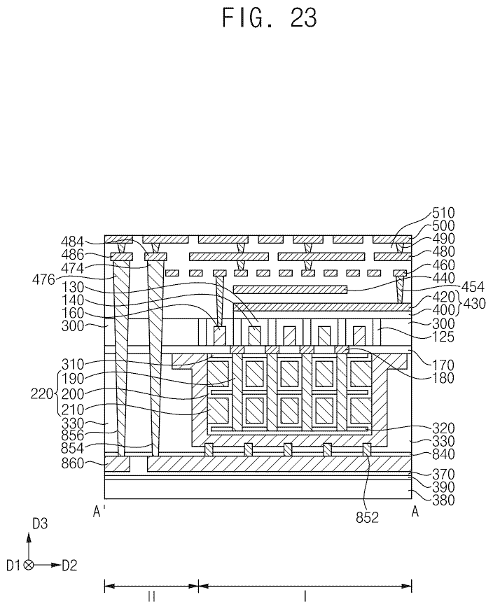

FIGS. 22 and 23 are schematic cross-sectional views illustrating a method of manufacturing a semiconductor device. This method may include processes substantially the same as or similar to those illustrated with reference to FIGS. 2 to 18 and FIG. 1, and thus repeated explanations are omitted herein.

Referring to FIG. 22, processes substantially the same as or similar to those illustrated with reference to FIGS. 2 to 7 may be performed.

However, the second and third conductive pads 184 and 186 may not be formed in the sixth insulating interlayer 170.

The second etch stop layer 840 and the fourteenth wiring 860 may be formed on the seventh insulating interlayer 330.

Referring to FIG. 23, processes substantially the same as or similar to those illustrated with reference to FIGS. 8 to 10 may be performed.

However, the eleventh insulating interlayer 870 may be formed on the seventh insulating interlayer 330 to cover the fourteenth wiring 860, and the second substrate 380 may be bonded to an upper surface of the eleventh insulating interlayer 370 with the temporary bonding layer 390 therebetween.

The second substrate 380 may be flipped, and each of the fifth and sixth contact plugs 474 and 476 may be formed through the eighth insulating interlayer 510, the fifth insulating interlayer 300, the sixth insulating interlayer 170, the seventh insulating interlayer 330 and the second etch stop layer 840 to electrically connect lower surfaces of the tenth and eleventh wirings 484 and 486, respectively, to an upper surface of the fourteenth wiring 860. The fifth and sixth contact plugs 474 and 476 may have a width in the horizontal direction that gradually increases from a bottom to a top thereof with increasing distance from the upper surface of the second substrate 380 in the third direction D3, due to the characteristics of the etching process for forming the fifth and sixth contact plugs 474 and 476.

Referring to FIG. 21 again, processes substantially the same as or similar to those illustrated with reference to FIGS. 11 to 18 may be performed, and the temporary bonding layer 390, the second substrate 380 and the eleventh insulating interlayer 870 may be removed from the seventh insulating interlayer 330, so that the fabrication of the semiconductor device may be completed.

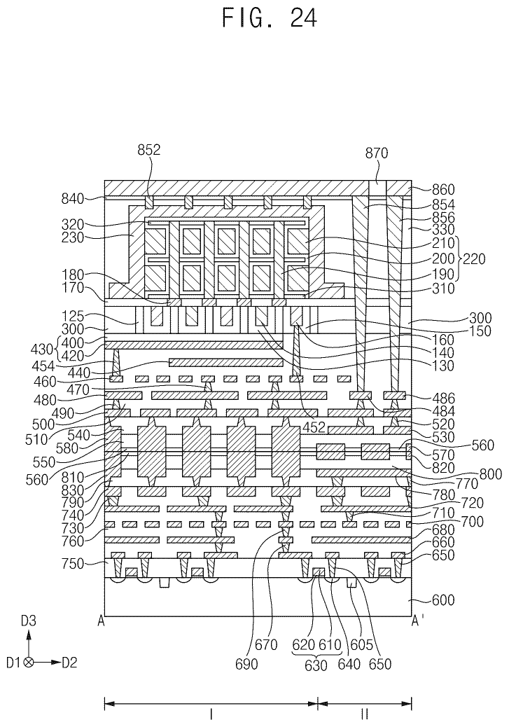

FIG. 24 is a schematic cross-sectional view illustrating a semiconductor device in accordance with example embodiments, which may correspond to FIG. 1. This semiconductor device may be substantially the same as or similar to that of FIG. 1 except for some elements, and thus repeated explanations are omitted herein.

Referring to FIG. 24, the semiconductor device may not include the fifth and sixth contact plugs 474 and 476, and the second and third conductive pads 184 and 186.

In example embodiments, each of the eighth and ninth contact plugs 854 and 856 may extend through the eighth insulating interlayer 510, the fifth insulating interlayer 300, the sixth insulating interlayer 170, the seventh insulating interlayer 330 and the second etch stop layer 840, and may contact upper surfaces of the tenth and eleventh wirings 484 and 486, respectively, and a lower surface of the fourteenth wiring 860. Each of the eighth and ninth contact plugs 854 and 856 may have a width in the horizontal direction that gradually increases from a bottom to a top thereof with increasing distance from the upper surface of the third substrate 600 in the third direction D3.

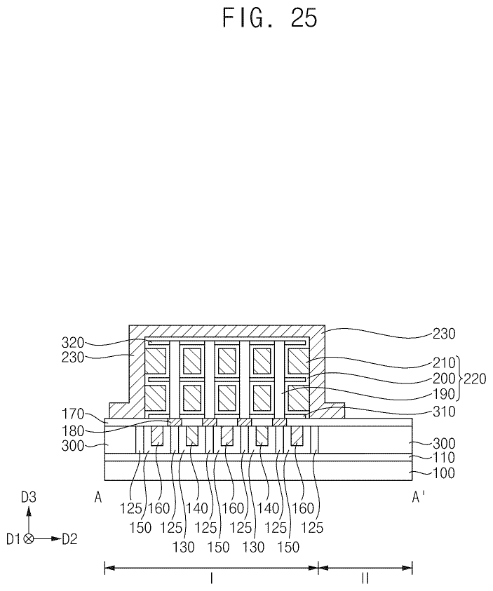

FIG. 25 is a schematic cross-sectional view illustrating a method of manufacturing a semiconductor device. This method may include processes substantially the same as or similar to those illustrated with reference to FIGS. 2 to 18 and FIG. 1, and thus repeated explanations are omitted herein.

Referring to FIG. 25, processes substantially the same as or similar to those illustrated with reference to FIGS. 2 to 7 may be performed.

However, the second and third conductive pads 184 and 186 may not be formed in the sixth insulating interlayer 170.

Referring to FIG. 24 again, processes substantially the same as or similar to those illustrated with reference to FIGS. 8 to 10 may be performed, however, the fifth and sixth contact plugs 474 and 476 may not be formed.

Processes substantially the same as or similar to those illustrated with reference to FIGS. 11 to 18 and FIG. 1 may be performed, so that the fabrication of the semiconductor device may be completed.

However, each of the eighth and ninth contact plugs 854 and 856 may be formed through the eighth insulating interlayer 510, the fifth insulating interlayer 300, the sixth insulating interlayer 170 and the seventh insulating interlayer 330 as well as the second etch stop layer 840 and the seventh insulating interlayer 330, and may contact a lower surface of the fourteenth wiring 860 and upper surfaces of the tenth and eleventh wirings 484 and 486, respectively.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor device, comprising:
a transistor on a substrate;
a first wiring structure on the transistor;
a first bonding pad structure on the first wiring structure;
a second wiring structure on the first wiring structure, the second wiring structure at least partially overlapping the first bonding pad structure in a horizontal direction parallel to an upper surface of the substrate;
a second bonding pad structure on and spaced apart from the second wiring structure, the second bonding pad structure overlapping the first bonding pad structure in the horizontal direction;
a bit line structure on the first and second bonding pad structures;
a gate structure on the bit line structure;
a channel adjacent to the gate structure, the channel in contact with the bit line structure; and
a capacitor on the channel.

2. The semiconductor device according to claim 1, wherein the second wiring structure includes:
a via in contact with a portion of the first wiring structure; and
a wiring in contact with an upper surface of the via opposite the substrate.

3. The semiconductor device according to claim 1, wherein the substrate includes first and second regions adjacent to each other in the horizontal direction, and
wherein the semiconductor device further comprises:
a plurality of first bonding pad structures spaced apart from each other in the horizontal direction on the first region of the substrate, the first bonding pad structure being one of the plurality of first bonding pad structures; and
a plurality of second bonding pad structures spaced apart from each other in the horizontal direction on the second region of the substrate, the second bonding pad structure being one of the plurality of second bonding pad structures.

4. The semiconductor device according to claim 3, wherein a distance in the horizontal direction between adjacent ones of the plurality of first bonding pad structures is the same as a distance in the horizontal direction between adjacent ones of the plurality of second bonding pad structures.

5. The semiconductor device according to claim 1, wherein the first and second bonding pad structures have a same width in the horizontal direction.

6. The semiconductor device according to claim 1, wherein the first bonding pad structure includes a middle portion having a first width in the horizontal direction, and lower and upper portions, adjacent to the middle portion, having a second width in the horizontal direction smaller than the first width.

7. The semiconductor device according to claim 1, further comprising a bonding layer structure on a sidewall of a portion of each of the first and second bonding pad structures.

8. The semiconductor device according to claim 7, wherein the bonding layer structure includes silicon carbonitride, and each of the first and second bonding pad structures includes copper.

9. The semiconductor device according to claim 1, wherein the first bonding pad structure includes first and second bonding pads sequentially stacked in a vertical direction perpendicular to the upper surface of the substrate, and the second bonding pad structure includes third and fourth bonding pads sequentially stacked in the vertical direction.

10. The semiconductor device according to claim 9, wherein upper surfaces of the first and third bonding pad structures are coplanar with each other.

11. The semiconductor device according to claim 1, further comprising a third wiring structure between the first and second bonding pad structures and the bit line structure,
wherein the first bonding pad structure is electrically connected to the third wiring structure.

12. A semiconductor device, comprising:
a transistor on a substrate;
a first wiring structure on the transistor;
a first bonding pad on the first wiring structure;
a second wiring structure on the first wiring structure, the second wiring structure at least partially overlapping the first bonding pad in a horizontal direction parallel to an upper surface of the substrate;
a second bonding pad in contact with an upper surface of the first bonding pad;
a third bonding pad in contact with an upper surface of the second wiring structure, the third bonding pad being spaced apart from the second bonding pad and overlapping the second bonding pad in the horizontal direction;
a third wiring structure on the second and third bonding pads;
a fourth wiring structure between the third bonding pad and the third wiring structure, the fourth wiring structure being spaced apart from the third bonding pad;
a bit line structure on the third wiring structure;
a gate structure on the bit line structure;
a channel adjacent to the gate structure, the channel being in contact with the bit line structure; and
a capacitor on the channel.

13. The semiconductor device according to claim 12, wherein the second wiring structure includes:
a first via in contact with a portion of the first wiring structure;
a first wiring in contact with an upper surface of the first via opposite the substrate;
a second via in contact with an upper surface of the first wiring; and
a second wiring in contact with an upper surface of the second via.

14. The semiconductor device according to claim 12, wherein an upper surface of the first bonding pad opposite the substrate and an upper surface of the second wiring structure opposite the substrate are coplanar with each other.

15. The semiconductor device according to claim 12, wherein a lower surface of the first bonding pad facing the substrate and a lower surface of the second wiring structure facing the substrate are coplanar with each other.

16. The semiconductor device according to claim 12, wherein the substrate includes first and second regions adjacent to each other in the horizontal direction, and
wherein the semiconductor device further comprises:
a plurality of first bonding pads spaced apart from each other in the horizontal direction on the first region of the substrate, the first bonding pad being one of the plurality of first bonding pads;
a plurality of second bonding pads spaced apart from each other in the horizontal direction on the first region of the substrate, the second bonding pad being one of the plurality of second bonding pads; and
a plurality of third bonding pads spaced apart from each other in the horizontal direction on the second region of the substrate, the third bonding pad being one of the plurality of third bonding pads.

17. The semiconductor device according to claim 12, wherein the first bonding pad includes a lower portion having a first width in the horizontal direction, and an upper portion having a second width in the horizontal direction greater than the first width, and
wherein the second bonding pad includes a lower portion having a third width in the horizontal direction, and an upper portion having a fourth width in the horizontal direction smaller than the third width.

18. The semiconductor device according to claim 12, further comprising a bonding layer on sidewalls of portions of the first bonding pad and the second wiring structure, the bonding layer including silicon carbonitride.

19. A semiconductor device, comprising:
a transistor on a substrate;
a first wiring structure on the transistor;
a first bonding pad on the first wiring structure;
a second wiring structure on the first wiring structure, the second wiring structure at least partially overlapping the first bonding pad in a horizontal direction parallel to an upper surface of the substrate;
a second bonding pad on and spaced apart from the second wiring structure, the second bonding pad overlapping the first bonding pad in the horizontal direction;
a third bonding pad in contact with an upper surface of the first bonding pad opposite the substrate;
a third wiring structure on the second and third bonding pads;
a fourth wiring structure between the second bonding pad and the third wiring structure, the fourth wiring structure being in contact with the third bonding pad;
a bit line structure on the third wiring structure;
a gate structure on the bit line structure;
a channel adjacent to the gate structure, the channel in contact with the bit line structure; and
a capacitor on the channel.

20. The semiconductor device according to claim 19, wherein:
the second wiring structure includes:
a first via in contact with a portion of the first wiring structure; and
a first wiring in contact with an upper surface of the first via opposite the substrate, and
the fourth wiring structure includes:
a second via in contact with a portion of the third wiring structure;
a second wiring in contact with a lower surface of the second via facing the substrate;
a third via in contact with a lower surface of the second wiring; and
a third wiring in contact with a lower surface of the third via and an upper surface of the third bonding pad.
